(19) United States
(12) Patent Application Publication
(10) Pub. No.: US 2013/0149494 A1
(43) Pub. Date: Jun. 13, 2013

(54) TiO2-CONTAINING QUARTZ-GLASS SUBSTRATE FOR AN IMPRINT MOLD AND MANUFACTURING METHOD THEREFOR

(71) Applicant: ASAHI GLASS COMPANY, LIMITED, Chiyoda-ku (JP)

(72) Inventors: Akio KOIKE, Tokyo (JP); Junko MIYASAKA, Tokyo (JP); Hiroshi NAKANISHI, Tokyo (JP)

(73) Assignee: ASAHI GLASS COMPANY, LIMITED, Chiyoda-ku (JP)

(21) Appl. No.: 13/740,786

(22) Filed: Jan. 14, 2013

Related U.S. Application Data
(63) Continuation of application No. PCT/JP2011/065497, filed on Jul. 6, 2011.

(30) Foreign Application Priority Data
Jul. 12, 2010 (JP) 2010-157811

(51) Int. Cl. G03F 7/00; B24B 9/10

(52) U.S. Cl. CPC G03F 7/0002; B24B 9/10
USPC 428/141; 451/44; 451/36

(57) ABSTRACT

The present invention relates to a TiO₂-containing quartz glass substrate for an imprint mold having a main surface and a side surface, in which the side surface has an arithmetic average roughness (Ra) of 1 nm or less, and the side surface has a root mean square (MSFR_rms) of concaves and convexes in the wavelength region of from 10 μm to 1 mm being 10 nm or less.

### TECHNICAL FIELD

The present invention relates to a TiO₂-containing quartz glass substrate for an imprint mold and manufacturing method therefor.

### BACKGROUND ART

As a method for forming a fine concave-convex pattern with a size of 1 nm to 10 μm on a surface of various substrates (for example, a single crystal substrate such as Si and sapphire, and an amorphous substrate such as glass) in a semiconductor device, an optical waveguide, a micro-optical element (such as diffraction grating), a biochip, a microreactor or the like, photo-imprint process of pressing an imprint mold having on a surface thereof a reversed pattern (transfer pattern) of a concave-convex pattern against a photocurable resin layer formed on a substrate surface and curing the photocurable resin layer to form the concave-convex pattern on the substrate surface is attracting attention.

The imprint mold used for the photo-imprint lithography is required to have light transmittance, chemical resistance and dimensional stability against temperature rise due to irradiation with light. As a substrate for an imprint mold, in view of light transmittance and chemical resistance, a quartz glass is often used. However, the quartz glass lacks dimensional stability, because its coefficient of thermal expansion at around room temperature is as high as about 500 ppb/° C. As regards a quartz-type glass having a low coefficient of thermal expansion, a TiO₂-containing quartz glass has been proposed.

### RELATED ART

### Patent Document

Patent Document 1: JP-A-2006-306674
Patent Document 2: WO2009/034954

### SUMMARY OF THE INVENTION

### Problems that the Invention is to Solve

However, since the TiO₂-containing quartz glass has striae (inhomogeneity of composition (composition distribution)), it is difficult to reduce roughness or waviness on the surface, particularly on the side surface of the TiO₂-containing quartz glass substrate, which is a substrate for an imprint mold, by polishing.

It has been found from the investigation of the present inventors that the following problems arise when there is a large roughness or waviness on the side surface of the TiO₂-containing quartz glass substrate.

(i) When there is a large roughness on the side surface of the TiO₂-containing quartz glass, fine particles of a polishing abrasive and the like used at the time of polishing the side surface are prone to attach to the side surface. Further, when the side surface of the TiO₂-containing quartz glass is grazed, fine particles are generated. The fine particles cause such problems that they go around and reach the main surface at the time of surface polishing after the side surface polishing to generate scratches on the main surface and they go around and reach the main surface at the time of batch-wise washing to reattach thereon. As a result, the fine particles cause defects in a concave-convex pattern that is transferred onto the surface of a substrate by an imprint process.

(ii) When there is a large waviness on the side surface of the TiO₂-containing quartz glass, a polishing abrasive (fine particles) used at the time of polishing the side surface is prone to attach thereto and the same problems as in (i) arise. Moreover, at the time of transferring a reversed pattern (transfer pattern) of an imprint mold to a substrate by an imprint process, even if the mold is intended to be positioned by bringing the side surface thereof into contact with a jig or the like, the position is shifted due to the waviness of the side surface. Therefore, the position of the concave-convex pattern transferred to the surface of the substrate by the imprint process is also shifted.

Accordingly, the present inventors have focused on stress caused by striae of the TiO₂-containing quartz glass substrate and have reached the present invention. The present invention provides a TiO₂-containing quartz glass substrate for an imprint mold capable of suppressing defects and positional shift of a concave-convex pattern to be transferred to a surface of the substrate by an imprint process at the time when the substrate is used as an imprint mold as well as a process for producing the same.

### Means for Solving the Problems

The TiO₂-containing quartz glass substrate for an imprint mold according to the present invention is a TiO₂-containing quartz glass substrate for an imprint mold having a main surface and a side surface, in which

the side surface has an arithmetic average roughness (Ra) of 1 nm or less, and

the side surface has a root mean square (MSFR_rms) of concaves and convexes in the wavelength region of from 10 μm to 1 mm being 10 nm or less.

The TiO₂-containing quartz glass substrate for an imprint mold according to the present invention preferably has a chamfered surface intervening between the main surface and the side surface for the purpose of preventing breakage or chipping, and the chamfered surface preferably has an arithmetic average roughness (Ra) of 1 nm or less.

The TiO₂-containing quartz glass substrate for an imprint mold according to the present invention preferably has a TiO₂ concentration of from 3 to 12 mass %.

The TiO₂-containing quartz glass substrate for an imprint mold according to the present invention preferably has a standard deviation (dev[σ]) of stress caused by striae being 0.05 MPa or less.

The TiO₂-containing quartz glass substrate for an imprint mold according to the present invention preferably has a difference (Δσ) between the maximum value and the minimum value of stress caused by striae of 0.23 MPa or less.

The method for producing a TiO₂-containing quartz glass substrate for an imprint mold according to one embodiment of the present invention is a method for producing a TiO₂-containing quartz glass substrate for an imprint mold having a main surface and a side surface, containing polishing a side surface of a TiO₂-containing quartz glass substrate having a standard deviation (dev[σ]) of stress caused by striae of 0.05 MPa or less, thereby controlling arithmetic average roughness (Ra) of the side surface to 1 nm or less and controlling root mean square (MSFR_rms) of concaves and convexes of the side surface in the wavelength region of from 10 μm to 1 mm to 10 nm or less.

The method for producing a TiO₂-containing quartz glass substrate for an imprint mold according to another embodiment of the present invention is a method for producing a TiO₂-containing quartz glass substrate for an imprint mold having a main surface and a side surface, containing polishing a side surface of a TiO₂-containing quartz glass substrate having a difference (Δσ) between the maximum value and the minimum value of stress caused by striae of 0.23 MPa or less, thereby controlling arithmetic average roughness (Ra) of the side surface to 1 nm or less and controlling root mean square (MSFR_rms) of concaves and convexes of the side surface in the wavelength region of from 10 μm to 1 mm to 10 nm or less.

In the method for producing a TiO₂-containing quartz glass substrate for an imprint mold according to the present invention, the side surface of the TiO₂-containing quartz glass substrate is preferably polished by relatively moving a polishing brush having bristles for brushes protruded therefrom against the TiO₂-containing quartz glass substrate, with feeding a polishing slurry containing a polishing abrasive.

In the method for producing a TiO₂-containing quartz glass substrate for an imprint mold according to the present invention, when the TiO₂-containing quartz glass substrate has a chamfered surface intervening between the main surface and the side surface, the method preferably contains polishing the chamfered surface together with the side surface of the TiO₂-containing quartz glass substrate, thereby controlling arithmetic average roughness (Ra) of the chamfered surface to 1 nm or less.

### Advantage of the Invention

The TiO₂-containing quartz glass substrate for an imprint mold of the present invention, when used as an imprint mold, can suppress defects and positional shift of a concave-convex pattern to be transferred to a surface of a substrate by an imprint process.

According to the method for producing a TiO₂-containing quartz glass substrate for an imprint mold of the present invention, there can be produced a TiO₂-containing quartz glass substrate for an imprint mold capable of, when used as an imprint mold, suppressing defects and positional shift of a concave-convex pattern to be transferred to a surface of a substrate by an imprint process.

### BRIEF DESCRIPTION OF THE DRAWINGS

FIG. 1 is a cross-sectional view of a vicinity of the peripheral edge showing one example of the TiO₂-containing quartz glass substrate for an imprint mold of the present invention.

FIG. 2 is a cross-sectional view of a vicinity of the peripheral edge showing another example of the TiO₂-containing quartz glass substrate for an imprint mold of the present invention.

### MODE FOR CARRYING OUT THE INVENTION

### <TiO₂-Containing Quartz Glass Substrate>

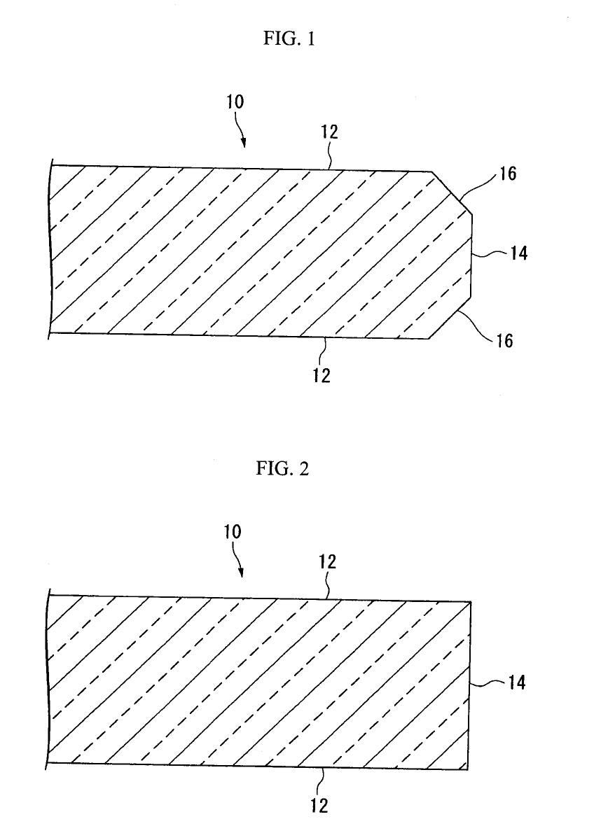

FIG. 1 is a cross-sectional view of a vicinity of the peripheral edge showing one example of the TiO₂-containing quartz glass substrate for an imprint mold of the present invention.

The TiO₂-containing quartz glass substrate 10 for an imprint mold has two main surfaces 12, a side surface 14 formed at the peripheral edge of the TiO₂-containing quartz glass substrate 10 for an imprint mold, and two chamfered surfaces 16 intervening between the main surfaces 12 and the side surface 14.

The TiO₂-containing quartz glass substrate 10 for an imprint mold preferably has the chamfered surface 16 from the viewpoint of suppressing breakage or chipping of an outer peripheral part but, as shown in FIG. 2, the substrate may not necessarily have the chamfered surface.

### (Arithmetic Average Roughness of Side Surface)

The side surface 14 has an arithmetic average roughness (Ra) of 1 nm or less, preferably 0.7 nm or less, and more preferably 0.5 nm or less. When the arithmetic average roughness (Ra) is 1 nm or less, fine particles of a polishing abrasive and the like used at the time of polishing the side surface 14 hardly attach to the side surface 14. Moreover, it is possible to remove the fine particles without problems on the main surfaces by performing scrub-washing of the side surface using a PVA sponge.

The arithmetic average roughness (Ra) is arithmetic average roughness (Ra) defined in JIS B 0601:2001 and is determined by measuring surface roughness in a region of 1 μm×1 μm using an atomic force microscope (AFM), followed by calculation from the result.

### (Root Mean Square of Concaves and Convexes of Side Surface)

The side surface 14 has a root mean square (MSFR_rms) of concaves and convexes in a wavelength region of from 10 μm to 1 mm being 10 nm or less, preferably 7 nm or less, and more preferably 5 nm or less. The root mean square (MSFR_rms) of concaves and convexes is an index of waviness of the side surface 14. When the root mean square (MSFR_rms) of concaves and convexes is 10 nm or less, fine particles of a polishing abrasive and the like used at the time of polishing the side surface 14 hardly attach to the side surface 14 and it is possible to remove the fine particles without problems on the main surfaces by performing scrub-washing of the side surface using a PVA sponge. Moreover, when the substrate is formed into an imprint mold, the positional shift caused by the waviness of the side surface 14 is hardly generated.

The side surface 14 preferably has a root mean square (MSFR_rms) of concaves and convexes in a wavelength region of from 10 μm to 1 mm of 0.1 nm or more, more preferably 0.5 nm or more, and further preferably 1 nm or more. When the root mean square (MSFR_rms) of concaves and convexes is 0.1 nm or more, contact area decreases and charging on the side surface 14 can be suppressed. Thus, the attachment of fine particles to the side surface 14 by charging can be suppressed.

The root mean square (MSFR_rms) of concaves and convexes in a wavelength region of 10 μm to 1 mm is determined by measuring surface roughness in a region of 2 mm×2 mm using a non-contact profilometer (for example, NewView manufactured by ZYGO Company or the like) and processing with a band pass filter to be a predetermined space region (10 μm to 1 mm), followed by calculation from the result.

### (Arithmetic Average Roughness of Chamfered Surface)

The chamfered surface 16 preferably has an arithmetic average roughness (Ra) of 1 nm or less, more preferably 0.7 nm or less, and further preferably 0.5 nm or less. When the arithmetic average roughness (Ra) is 1 nm or less, fine particles of a polishing abrasive and the like used at the time of polishing the chamfered surface 16 hardly attach to the chamfered surface 16. Moreover, it is possible to remove the fine particles without problems on the main surfaces by performing scrub-washing of the side surface using a PVA sponge.

### (TiO₂ Concentration)

The TiO₂-containing quartz glass substrate 10 for an imprint mold (100 mass %) preferably has a TiO₂ concentration of from 3 to 12 mass %. Since the TiO₂-containing quartz glass substrate 10 for an imprint mold is used as a substrate for an imprint mold, dimensional stability against temperature change is required. When the TiO₂ concentration is from 3 to 12 mass %, the coefficient of thermal expansion at around room temperature can be made small. In order to make the coefficient of thermal expansion at around room temperature almost zero, the TiO₂ concentration is more preferably from 5 to 9 mass % and still more preferably from 6 to 8 mass %.

The TiO₂ concentration is measured by using a fundamental parameter (FP) method in the fluorescence X-ray analysis.

### (Ti³⁺ Concentration)

The TiO₂-containing quartz glass substrate 10 for an imprint mold preferably has a Ti³⁺ concentration of, on average, 100 ppm by mass or less, more preferably 70 ppm by mass or less, still more preferably 20 ppm by mass or less, and particularly preferably 10 ppm by mass or less. The Ti³⁺ concentration affects the coloration of TiO₂-containing quartz for an imprint mold, particularly, the internal transmittance T₃₀₀₋₇₀₀. When the Ti³⁺ concentration is 100 ppm by mass or less, brown coloration can be suppressed, and as a result, reduction in the internal transmittance T₃₀₀₋₇₀₀ can be suppressed, leading to good transparency.

The Ti³⁺ concentration is determined by electron spin resonance (ESR: Electron Spin Resonance) measurement. The measurement conditions are as follows.

Frequency: around 9.44 GHz (X-band),

Output: 4 mW,

Modulated magnetic field: 100 KHz, 0.2 mT,

Measurement temperature: room temperature

ESR species integration range: 332 to 368 mT, and

Sensitivity calibration: conducted at a peak height of a given amount of Mn²⁺/MgO.

In the ESR signal (differential form) in which the ordinate axis is signal intensity and the abscissa axis is magnetic field intensity (mT), a TiO₂-containing quartz glass substrate for an imprint mold shows a profile having an anisotropy of g₁=1.988, g₂=1.946 and g₃=1.915. Since Ti³⁺ in glass is usually observed at g=around 1.9, those signals are taken as signals derived from Ti³⁺. The Ti³⁺ concentration is determined by comparing the intensity after twice integration with the corresponding intensity after twice integration of a standard sample whose concentration is known.

The TiO₂-containing quartz glass for an imprint mold preferably has a ratio (ΔTi³⁺/Ti³⁺) of the variation in the Ti³⁺ concentration to the average value of the Ti³⁺ concentration being 0.2 or less, more preferably 0.15 or less, and still more preferably 0.1 or less. When ΔTi³⁺/Ti³⁺ is 0.2 or less, coloration and distribution of characteristics such as distribution of absorption coefficient, are reduced.

ΔTi³⁺/Ti³⁺ is determined by the following method.

Measurement is performed every 10 mm from one end to the other end on an arbitrary line passing the center point of the sample main surface. The difference between the maximum value and the minimum value of the Ti³⁺ concentration is taken as ΔTi³⁺ and divided by the average value of the Ti³⁺ concentration to determine ΔTi³⁺/Ti³⁺.

### (OH Concentration)

The TiO₂-containing quartz glass substrate 10 for an imprint mold preferably has an OH concentration of less than 600 ppm by mass, more preferably 400 ppm by mass or less, still more preferably 200 ppm by mass or less, and particularly preferably 100 ppm by mass or less. When the OH concentration is less than 600 ppm by mass, reduction in the light transmittance in the near infrared region due to absorption by OH group can be suppressed, and T₃₀₀₋₃₀₀₀ hardly becomes less than 80%.

The OH concentration is determined by the following method.

Measurement by an infrared spectrophotometer is performed and the OH concentration is determined from an absorption peak at a wavelength of 2.7 μm (J. P. Williams et al., Ceramic Bulletin, 55(5), 524, 1976). The detection limit by this method is 0.1 ppm by mass.

### (Halogen Concentration)

The TiO₂-containing quartz glass substrate 10 for an imprint mold preferably has a halogen concentration of less than 50 ppm by mass, more preferably 20 ppm by mass or less, still more preferably 1 ppm by mass or less, and particularly preferably 0.1 ppm by mass or less. When the halogen concentration is less than 50 ppm by mass, the Ti³⁺ concentration hardly increases, so that the brown coloration is less likely to occur. As a result, decrease of T₃₀₀₋₇₀₀ is inhibited and the transparency is not impaired.

The halogen concentration is determined by the following method.

The chlorine concentration is determined by quantitative analysis of chlorine ion concentration by an ion chromatographic analytical method, for a solution obtained by dissolving a sample in a sodium hydroxide solution under heating, followed by filtration through a cation-removing filter.

The fluorine concentration is determined by a fluorine ion electrode method. Specifically, in accordance with the method disclosed in Journal of Chemical Society of Japan, 1972 (2), 350, a sample is heated and melted in anhydrous sodium carbonate, and to the obtained melt, distilled water and hydrochloric acid (in a volume ratio of 1:1) are added, whereby a sample solution is prepared. The electromotive force of the sample solution is measured by a radiometer by using No. 945-220 and No. 945-468, both are manufactured by Radiometer Trading, as a fluorine ion selective electrode and a comparative electrode, respectively, and the fluorine concentration is determined based on a calibration curve preliminarily created by using fluorine ion standard solutions.

### (Internal Transmittance)

The TiO₂-containing quartz glass substrate 10 for an imprint mold preferably has an internal transmittance T₃₀₀₋₇₀₀ per 1 mm thickness in the wavelength region of 300 to 700 nm being 70% or more, more preferably 80% or more, and still more preferably 85% or more. In the photo-imprint lithography, since a photocurable resin is cured by ultraviolet irradiation, higher ultraviolet transmittance is preferable.

The TiO₂-containing quartz glass substrate 10 for an imprint mold preferably has an internal transmittance T₄₀₀₋₇₀₀ per 1 mm thickness in the wavelength region of 400 to 700 nm being 80% or more, more preferably 85% or more, and still more preferably 90% or more. When T₄₀₀₋₇₀₀ is 80% or more, visible light is hardly absorbed, as a result, the presence or absence of an internal defect such as bubbles and striae is easily judged at the inspection with a microscope, an eye or the like, and a problem is less likely to occur in the inspection or evaluation.

The TiO₂-containing quartz glass substrate 10 for an imprint mold preferably has an internal transmittance T₃₀₀₋₃₀₀₀ per 1 mm thickness in the wavelength region of 300 to 3,000 nm being 70% or more, more preferably 80% or more, and still more preferably 85% or more. When T₃₀₀₋₃₀₀₀ is 70% or more, the ultraviolet transmittance is high and also light absorption in the range of from visible light region to near infrared light region is suppressed and therefore a temperature rise due to light absorption is suppressed.

The internal transmittance is determined by the following method.

The transmittance of a sample (mirror-polished TiO₂-containing quartz glass substrate for an imprint mold) is measured using a spectrophotometer. The internal transmittance per 1 mm of thickness is determined by measuring respective transmittance of samples different in thickness, which are mirror-polishing to the same degree, for example, a sample with a thickness of 2 mm and a sample with a thickness of 1 mm, converting each transmittance into absorbance, subtracting the absorbance of the sample with a thickness of 1 mm from the absorbance of the sample with a thickness of 2 mm to obtain an absorbance per 1 mm of thickness, and again converting the absorbance into a transmittance.

As another method, a quartz glass having about 1 mm thickness, which has been mirror-polished to the same degree as in the case of the sample, is prepared. A decrease of transmittance of the quartz glass at a wavelength at which the quartz glass does not absorb, for example, at a wavelength of around 2,000 nm, is taken as reflection loss at front surface and back surface. The decrease of transmittance is converted into an absorbance, which is taken as absorbance of reflection loss at front surface and back surface.

The transmittance of a sample with a thickness of 1 mm in a wavelength region of measuring the internal transmittance is converted into an absorbance and the absorbance of the quartz glass at a wavelength of 2,000 nm is subtracted therefrom. The difference in absorbance is again converted into a transmittance, which is taken as internal transmittance.

### (Stress)

The TiO₂-containing quartz glass substrate 10 for an imprint mold preferably has a standard deviation (dev[σ]) of stress caused by striae of 0.05 MPa or less, more preferably 0.04 MPa or less, and still more preferably 0.03 MPa or less. Usually, a glass body obtained by a soot process to be mentioned later is also said to be three-direction striae-free, and striae are not observed therein. However, even in the case of a glass body produced by a soot process, there is a possibility that striae are observed when a dopant (TiO₂ or the like) is contained. When striae are present, it is difficult to obtain a surface having little roughness and waviness even when polishing is conducted. Moreover, for the same reason, the TiO₂-containing quartz glass substrate 10 for the imprint mold preferably has a difference (Δσ) between the maximum value and the minimum value of stress caused by striae of 0.23 MPa or less, more preferably 0.2 MPa or less, and still more preferably 0.15 MPa or less.

The stress is determined by the following method.

First, retardation of a sample is determined by measuring a region of about 1 mm×1 mm using a birefringence microscope, and a profile of stress is determined from the following equation (1).

Δ=C×F×n×d (1)

Here, Δ is retardation, C is a photoelastic constant, F is stress, n is a refractive index, and d is a thickness of the sample.

Then, the standard deviation (dev[σ]) of stress and the difference (Δσ) between the maximum value and the minimum value of the stress are determined from the stress profile.

Specifically, a sample is cut out of a TiO₂-containing quartz glass substrate 10 for an imprint mold by slicing, followed by polishing, thereby obtaining a plate-shaped sample of 30 mm×30 mm×0.5 mm. Using a birefringence microscope, helium neon laser light is vertically applied onto a 30 mm×30 mm surface of the sample, and the in-plane retardation distribution is examined at an enlarging magnification high enough to enable adequate observation of striae and converted into a stress distribution. In the case where the pitch of striae is fine, the thickness of the sample must be made thinner.

### (Coefficient of Thermal Expansion)

The TiO₂-containing quartz glass substrate 10 for an imprint mold preferably has a coefficient of thermal expansion, C₁₅₋₃₅, at 15 to 35° C. being in the range of 0±200 ppb/° C. In the case when used as a substrate for an imprint mold, the TiO₂-containing quartz glass substrate 10 for an imprint mold is required to be excellent in dimensional stability against a temperature change, more specifically, excellent in dimensional stability against a temperature change in the temperature region capable of being experienced by the mold during the imprint process. Here, the temperature region capable of being experienced by the imprint mold varies depending on the kind of the imprint process. In the photo-imprint process, since a photocurable resin is cured by ultraviolet irradiation, the temperature region capable of being experienced by the mold is fundamentally around room temperature. However, the temperature of the mold sometimes is locally elevated due to ultraviolet irradiation. Considering the local temperature rising due to ultraviolet irradiation, it is assumed that the temperature region capable of being experienced by the mold is from 15 to 35° C. C₁₅₋₃₅ is more preferably in the range of 0±100 ppb/° C., still more preferably in the range of 0±50 ppb/° C., and particularly preferably in the range of 0±30 ppb/° C.

The TiO₂-containing quartz glass substrate 10 for an imprint mold preferably has a coefficient of thermal expansion, C₂₂, at 22° C. of 0±30 ppb/° C., more preferably 0±10 ppb/° C., and still more preferably 0±5 ppb/° C. When C₂₂ is in the range of 0±30 ppb/° C., the dimensional change due to temperature change is negligible, regardless of whether the value is positive or negative.

In order to make an accurate measurement with a small number of measurement points as in the case of the coefficient of thermal expansion at 22° C., dimensional change of a sample due to temperature change of 1 to 3° C. lower and higher the objective temperature is measured by using a laser heterodyne interferometric thermal dilatometer (for example, CTE-01, manufactured by Uniopt or the like), and an average coefficient of thermal expansion determined is taken as the coefficient of thermal expansion at the middle temperature.

### (Fictive Temperature Distribution)

The TiO₂-containing quartz glass substrate 10 for an imprint mold preferably has a fictive temperature distribution in the region from the main surface to a depth of 10 μm on the side to be subjected to a transfer pattern formation being within ±30° C., and the fictive temperature distribution is more preferably within ±20° C., and the fictive temperature distribution is still more preferably within ±10° C. When the fictive temperature distribution is within ±30° C., the variation in etching rate at the time of forming a transfer pattern through etching on the main surface of the TiO₂-containing quartz glass substrate 10 for an imprint mold can be reduced.

The fictive temperature is determined by the following method.

(i) A sample whose fictive temperature is unknown is prepared. The sample is a mirror-polished TiO₂-containing quartz glass substrate 10 for an imprint mold.

(ii) A plurality of kinds of glass bodies differing in the fictive temperature, each of which is a glass body having a known fictive temperature and having the same composition as the sample described above, are prepared. The surfaces of the glass bodies are previously mirror-polished.

(iii) The infrared reflection spectrum on the surface of each of the glass bodies of (ii) is obtained by using an infrared spectrometer (Magna 760, manufactured by Nikolet). The reflection spectrum is the average value obtained by scanning 256 times or more. In the obtained infrared reflection spectrum, a peak observed in the vicinity of about 1,120 cm⁻¹ is a peak attributed to stretching vibration by an Si—O—Si bond of the glass, and the peak position depends on the fictive temperature. A calibration curve which shows the relationship between the peak position and the fictive temperature and obtained with the plurality of kinds of glass bodies differing in the fictive temperature, is prepared.

(iv) An infrared reflection spectrum of the sample of (i) is obtained under the same conditions as in (iii) described above. In the obtained infrared reflection spectrum, the position of a peak observed in the vicinity of about 1,120 cm⁻¹, which is attributed to stretching vibration by an Si—O—Si bond, is exactly determined. The fictive temperature is determined by comparing this peak position with the calibration curve.

Also, the fictive temperature distribution in the region from the surface to a depth of 10 μm is determined as follows.

First, the fictive temperature of the surface is determined by the method described above. Subsequently, the glass body is immersed in a 10 mass % hydrofluoric acid solution for 30 seconds to 1 minute, and the mass decrease between before and after immersion is determined. From the mass decrease, the etched depth is determined according to the following formula (2).

(Etched depth)=(Mass decrease)/((Density)×(Surface area)) (2).

Moreover, the fictive temperature of the surface exposed after the etching is determined by the method mentioned above and is taken as the fictive temperature at that depth. Thereafter, the glass body is again immersed in a 10 mass % hydrofluoric solution for 30 seconds to 1 minute, and the depth and the fictive temperature are determined. By repeating this operation, the maximum value and the minimum value out of the fictive temperature values obtained by operations immediately before the depth exceeds 10 μm are determined, and the difference therebetween is taken as the fictive temperature distribution in the region from the surface to a depth of 10 μm.

### (Function and Effect)

In the TiO₂-containing quartz glass substrate 10 for an imprint mold described in the above, since the side surface 14 has an arithmetic average roughness (Ra) of 1 nm or less and has a root mean square (MSFR_rms) of concaves and convexes in the wavelength region of 10 μm to 1 mm being 10 nm or less, the fine particles of the polishing abrasive and the like used at the time of polishing the side surface 14 hardly attach to the side surface. Moreover, it is possible to remove the fine particles without causing problems on the main surface by performing scrub-washing of the side surface using a PVA sponge. As a result, fine particles are hardly generated when the side surface 14 of the TiO₂-containing quartz glass substrate 10 for an imprint mold is grazed, and such problems that they go around and reach the main surface at the time of main surface polishing after the side surface polishing to generate scratches and they go around and reach the main surface at the time of batch-wise washing to attach thereon can be suppressed. Therefore, defects caused by the fine particles and scratches in a concave-convex pattern transferred onto the surface of a substrate by an imprint process are suppressed. Moreover, since the root mean square (MSFR_rms) is 10 nm or less, the positional shift caused by the waviness of the side surface 14 is hardly generated at the time of forming an imprint mold. As a result, the positional shift of the concave-convex pattern transferred onto the surface of the substrate by the imprint process is suppressed.

### <Method for Producing TiO₂-Containing Quartz Glass Substrate for Imprint Mold>

The method for producing a TiO₂-containing quartz glass substrate for an imprint mold of the present invention is a process containing polishing a side surface of an unpolished TiO₂-containing quartz glass substrate having (I) a standard deviation (dev[σ]) of stress caused by striae of 0.05 MPa or less and/or (II) a difference (Δσ) between the maximum value and the minimum value of stress caused by striae of 0.23 MPa or less, thereby controlling arithmetic average roughness (Ra) of the side surface to 1 nm or less and controlling root mean square (MSFR_rms) of concaves and convexes of the side surface in the wavelength region of 10 μm to 1 mm to 10 nm or less.

In the case where the TiO₂-containing quartz glass substrate has a chamfered surface, the chamfered surface is preferably polished together with the side surface of the unpolished TiO₂-containing quartz glass substrate, thereby controlling arithmetic average roughness (Ra) of the chamfered surface to 1 nm or less.

A specific example of the production method according to the present invention is described below in detail.

The method for producing a TiO₂-containing quartz glass substrate for an imprint mold (hereinafter, referred to as a TiO₂—SiO₂ glass substrate) includes a method containing the following steps (a) to (f):

(a) a step of depositing TiO₂—SiO₂ glass fine particles obtained from a glass-forming raw material containing an SiO₂ precursor and a TiO₂ precursor by a soot process to obtain a porous TiO₂—SiO₂ glass body.
(b) a step of heating the porous TiO₂—SiO₂ glass body to densification temperature to obtain a TiO₂—SiO₂ dense body,
(c) a step of heating the TiO₂—SiO₂ dense body to transparent vitrification temperature to obtain a transparent TiO₂—SiO₂ glass body,
(d) a step of, if desired, heating the transparent TiO₂—SiO₂ glass body to softening point or higher and molding to obtain a molded TiO₂—SiO₂ glass body,
(e) a step of annealing the transparent TiO₂—SiO₂ glass body obtained in step (c) or the molded TiO₂—SiO₂ glass body obtained in step (d), and
(f) a step of subjecting the TiO₂—SiO₂ glass body obtained in step (e) to machining such as cutting, shaving and polishing to obtain a TiO₂—SiO₂ glass substrate having a predetermined shape.

### (Step (a))

By a soot process, TiO₂—SiO₂ glass fine particles (soot) obtained by flame hydrolysis or thermal decomposition of a SiO₂ precursor and a TiO₂ precursor each serving as a glass-forming raw material is deposited and grown on a substrate for deposition which constantly rotates on an axis at a certain speed, whereby a porous TiO₂—SiO₂ glass body is formed.

Examples of the soot process include an MCVD process, an OVD process and a VAD process. The VAD process is preferred from the standpoint that, for example, the mass productivity is excellent and a glass body having a uniform composition in a large-area plane can be obtained by adjusting the production conditions such as size of a substrate for deposition.

The glass-forming raw material includes a gasifiable raw material.

The SiO₂ precursor includes a silicon halide compound and an alkoxysilane.

The TiO₂ precursor includes a titanium halide compound and an alkoxytitanium.

The silicon halide compound includes a chloride (e.g., SiCl₄, SiHCl₃, SiH₂Cl₂, SiH₃Cl), a fluoride (e.g., SiF₄, SiHF₃, SiH₂F₂), a bromide (e.g., SiBr₄, SiHBr₃), and an iodide (e.g., SiI₄).

The alkoxysilane includes a compound represented by the following formula (3).

RₙSi(OR)₄₋ₙ (3)

Here, R is an alkyl group having a carbon number of 1 to 4, n is an integer of 0 to 3, and a part of Rs out of the plural Rs may be different.

Examples of the titanium halide compound include TiCl₄ and TiBr₄.

The alkoxytitanium includes a compound represented by the following formula (4).

RₙTi(OR)₄₋ₙ (4)

Here, R is an alkyl group having a carbon number of 1 to 4, n is an integer of 0 to 3, and a part of Rs out of the plural Rs may be different.

As the SiO₂ precursor and the TiO₂ precursor, a compound containing Si and Ti, such as silicon titanium double alkoxide, may be used.

The substrate for deposition includes a quartz glass-made seed rod (for example, the seed rod described in JP-B-63-24937). The shape is not limited to a rod form, and a plate-shaped substrate for deposition may be also used.

### (Step (b))

The porous TiO₂—SiO₂ glass body obtained in step (a) is heated to densification temperature in an inert gas atmosphere or a reduced pressure atmosphere to obtain a TiO₂—SiO₂ dense body.

The densification temperature means a temperature at which a porous TiO₂—SiO₂ glass body can be densified to such an extent that a void cannot be observed by an optical microscope.

The densification temperature is preferably from 1,250 to 1,550° C., and more preferably from 1,350 to 1,450° C.

The inert gas is preferably helium.

The pressure in the atmosphere is preferably from 10,000 to 200,000 Pa. In the present description, Pa means not a gauge pressure but an absolute pressure.

In step (b), it is preferred that the porous TiO₂—SiO₂ glass body is placed under reduced pressure (preferably 13,000 Pa or lower, and more preferably 1,300 Pa or lower) and then, an inert gas is introduced to create an inert gas atmosphere of a predetermined pressure, because homogeneity of the TiO₂—SiO₂ dense body is increased.

Also, in step (b), it is preferred that the porous TiO₂—SiO₂ glass body is held in an inert gas atmosphere at room temperature or a temperature lower than the densification temperature and then, the temperature is raised to the densification temperature, because homogeneity of the TiO₂—SiO₂ dense body is increased.

### (Step (c))

The TiO₂—SiO₂ dense body obtained in step (b) is heated to transparent vitrification temperature to obtain a transparent TiO₂—SiO₂ glass body.

The transparent vitrification temperature means a temperature at which a crystal cannot be observed by an optical microscope and a transparent glass is obtained.

The transparent vitrification temperature is preferably from 1,350 to 1,750° C., and more preferably from 1,400 to 1,700° C.

The atmosphere is preferably an atmosphere of 100% inert gas (e.g., helium, argon), or an atmosphere containing the inert gas (e.g., helium, argon) as a main component.

The pressure of the atmosphere is preferably reduced pressure or normal pressure. In the case of reduced pressure, the pressure is preferably 13,000 Pa or lower.

### (Step (d))

The transparent TiO₂—SiO₂ glass body obtained in step (c) is placed in a mold and heated to a temperature of softening point or higher, thereby molded into a desired shape to obtain a molded TiO₂—SiO₂ glass body.

The molding temperature is preferably from 1,500 to 1,800° C. When the molding temperature is 1,500° C. or higher, the transparent TiO₂—SiO₂ glass body is reduced in viscosity and easily deformed due to its own weight. Also, growth of cristobalite that is a crystal phase of SiO₂, or growth of rutile or anatase that are a crystal phase of TiO₂, is suppressed, and so-called devitrification hardly occurs. When the molding temperature is 1,800° C. or lower, sublimation of SiO₂ is suppressed.

Step (d) may be repeated a plurality of times. For example, two-stage molding may be performed such that after the transparent TiO₂—SiO₂ glass body is placed in a mold and heated to a temperature of softening point or higher, and the molded TiO₂—SiO₂ glass body obtained is placed in another mold and again heated to a temperature of softening point or higher.

Also, step (c) and step (d) may be performed sequentially or simultaneously.

In the case where the transparent TiO₂—SiO₂ glass body obtained in step (c) is sufficiently large, a molded TiO₂—SiO₂ glass body may be obtained by cutting the transparent TiO₂—SiO₂ glass body obtained in step (c) into a predetermined shape without performing the subsequent step (d).

The following step (d′) may be performed in place of step (d), or after step (d) and before step (e).

(Step (d′))

(d′) This is a step of heating the transparent TiO₂—SiO₂ glass body obtained in step (c) or the molded TiO₂—SiO₂ glass body obtained in step (d) at a temperature of T₁+400° C. or higher for 20 hours or more.

T₁ is the annealing point (° C.) of the TiO₂—SiO₂ glass body obtained in step (e).

The annealing point means a temperature at which the viscosity η of a glass becomes 1013 dPa·s. The annealing point is determined as follows.

Viscosity of a glass is measured by a beam bending method in accordance with JIS R 3103-2:2001, and the temperature at which the viscosity η becomes 1013 dPa·s is defined as the annealing point.

By performing step (d′), striae in the TiO₂—SiO₂ glass body are reduced.

The “striae” indicates a compositional non-uniformity (composition distribution) in the TiO₂—SiO₂ glass body. In the TiO₂—SiO₂ glass body having striae, sites differing in the TiO₂ concentration are present. A site with a high TiO₂ concentration has a negative coefficient of thermal expansion (CTE) and therefore, the site with a high TiO₂ concentration tends to expand during cooling process in step (e). At this time, when a site with a low TiO₂ concentration is present adjacent to the site with a high TiO₂ concentration, expansion of the site with a high TiO₂ concentration is inhibited, and a compression stress is added. As a result, a stress distribution is generated in the TiO₂—SiO₂ glass body. Hereinafter, in the present description, such a stress distribution is referred to as a “stress distribution caused by striae”.

The compositional non-uniformity in the TiO₂—SiO₂ glass body can be reduced also by increasing a rotating speed of a substrate for deposition in step (a). The rotating speed is preferably 5 rpm or more, more preferably 20 rpm or more, further preferably 50 rpm or more, and most preferably 100 rpm or more.

When a stress distribution caused by striae is present in a TiO₂—SiO₂ glass body used as a substrate for an imprint mold, a difference is produced in processing rate at the time of polishing the surface, and this affects roughness or waviness of the surface after the polishing.

By performing step (d) or step (d′), the stress distribution caused by striae in the TiO₂—SiO₂ glass body produced through the subsequent step (e) is reduced to a level bringing about no problem in use as a substrate for an imprint mold.

The heating temperature in step (d′) is preferably lower than T₁+600° C., more preferably lower than T₁+550° C., and still more preferably lower than T₁+500° C., from the standpoint that foaming or sublimation in the TiO₂—SiO₂ glass body is suppressed. That is, the heating temperature in step (d′) is preferably from T₁+400° C. to lower than T₁+600° C., more preferably from T₁+400° C. to lower than T₁+550° C., and still more preferably from T₁+450° C. to lower than T₁+500° C.

From the standpoint of, for example, balancing the effect of reducing striae and the yield of TiO₂—SiO₂ glass body and reducing the cost, the heating time in step (d′) is preferably 240 hours or less, and more preferably 150 hours or less. Also, in view of the effect of reducing striae, the heating time is preferably over 24 hours, more preferably over 48 hours, and still more preferably over 96 hours.

Step (d′) and step (e) may be performed sequentially or simultaneously. Also, step (c) and/or step (d), and step (d′) may be performed sequentially or simultaneously.

### (Step (e))

The transparent TiO₂—SiO₂ glass body obtained in step (c), the molded TiO₂—SiO₂ glass body obtained in step (d), or the TiO₂—SiO₂ glass body obtained in step (d′) is subjected to an annealing treatment of heating to a temperature of 1,100° C. or higher and then, cooling to a temperature of 700° C. or lower at an average cooling rate of 100° C./hr or lower, whereby the fictive temperature of the TiO₂—SiO₂ glass body is controlled.

In the case of performing step (c) or step (d) and step (e) sequentially or simultaneously, during the cooling process of from the temperature of 1,100° C. or higher in step (c) or step (d), an annealing treatment of cooling the obtained transparent TiO₂—SiO₂ glass body or molded TiO₂—SiO₂ glass body from 1,100° C. to 700° C. at an average cooling rate of 100° C./hr or lower is performed, whereby the fictive temperature of the TiO₂—SiO₂ glass body is controlled.

The average cooling rate is preferably 10° C./hr or lower, more preferably 5° C./hr or lower, and still more preferably 2.5° C./hr or lower.

After cooling to a temperature of 700° C. or lower, the glass body can be allowed to stand to be cooled. The atmosphere is not particularly limited.

In order to eliminate inclusions such as foreign matters and bubbles from the TiO₂—SiO₂ glass body obtained in step (e), it is crucial to inhibit contamination in steps (a) to (d) (particularly, in step (a)) and furthermore, precisely control the temperature condition in steps (b) to (d).

The above-described steps (a) to (e) are an example showing the production method of a TiO₂—SiO₂ glass body when a soot process is employed in step (a). In the case of employing a direct process in step (a), a transparent TiO₂—SiO₂ glass body can be obtained directly without performing step (b) and step (c). The direct process is a process of obtaining a transparent TiO₂—SiO₂ glass body directly by hydrolyzing/oxidizing an SiO₂ precursor and a TiO₂ precursor each serving as a glass-forming raw material in oxyhydrogen flame at 1,800 to 2,000° C. to form TiO₂—SiO₂ glass fine particles and depositing them at transparent vitrification temperature. Subsequently to step (a) by the direct process, step (d) and step (e) may be sequentially performed. Also, the transparent TiO₂—SiO₂ glass body obtained by the direct process in step (a) may be cut into a predetermined dimension to obtain a molded TiO₂—SiO₂ glass body, and thereafter, step (e) may be performed. The transparent TiO₂—SiO₂ glass body obtained by the direct process in step (a) contains H₂ or OH. By adjusting the flame temperature or gas concentration in the direct process, OH concentration in the transparent TiO₂—SiO₂ glass body can be controlled. The OH concentration in the transparent TiO₂—SiO₂ glass body can be controlled also by a method of holding the transparent TiO₂—SiO₂ glass body obtained by the direct process in step (a), in a vacuum, in a reduced pressure atmosphere, or in the case of normal pressure, in an atmosphere having an H₂ concentration of 1,000 ppm by volume or less and an O₂ concentration of 18 vol % or less, at a temperature of 700 to 1,800° C. for 10 minutes to 90 days, thereby performing degassing.

### (Step (f))

The TiO₂—SiO₂ glass body obtained in step (e) is subjected to machining such as cutting, shaving and polishing, whereby a TiO₂—SiO₂ glass substrate having a predetermined shape is obtained. In the present invention, at least polishing is performed.

The polishing step is preferably performed in parts in two or more steps depending on the finished condition of the polished surface. In the final polishing step, colloidal silica is preferably used as a polishing abrasive.

In the present invention, from the viewpoint of easiness of controlling arithmetic average roughness (Ra) of the side surface to 1 nm or less and controlling root mean square (MSFR_rms) of concaves and convexes of the side surface in the wavelength region of 10 μm to 1 mm to 10 nm or less, it is preferred to perform a polishing by relatively moving a polishing brush having bristles for brushes protruded therefrom against a TiO₂—SiO₂ glass body, with feeding a polishing slurry containing a polishing abrasive. The polishing abrasive includes SHOROX A-10 (KT) manufactured by Showa Denko K.K. and bristles for brushes include one which material is PP (polypropylene), brush diameter is φ 0.5, and shape is wave.

### (Function and Effect)

In the method for producing a TiO₂-containing quartz glass substrate for an imprint mold of the present invention described in the above, since the side surface of a TiO₂-containing quartz glass substrate having (I) a standard deviation (dev[σ]) of stress caused by striae of 0.05 MPa or less and/or (II) a difference (Δσ) between the maximum value and the minimum value of stress caused by striae of 0.23 MPa or less, i.e., having a small striae, is polished, arithmetic average roughness (Ra) of the side surface can be controlled to 1 nm or less and root mean square (MSFR_rms) of concaves and convexes of the side surface in the wavelength region of 10 μm to 1 mm can be controlled to 10 nm or less.

Moreover, by polishing the side surface of the TiO₂-containing quartz glass substrate by relatively moving a polishing brush having bristles for brushes protruded therefrom against the TiO₂-containing quartz glass substrate with feeding a polishing slurry containing a polishing abrasive, arithmetic average roughness (Ra) of the side surface can be controlled to 1 nm or less and root mean square (MSFR_rms) of concaves and convexes of the side surface in the wavelength region of 10 μm to 1 mm can be controlled to 10 nm or less.

### <Imprint Mold>

An imprint mold can be produced by forming a transfer pattern on a main surface of the TiO₂-containing quartz glass substrate for an imprint mold of the present invention by etching.

The transfer pattern is a reversed pattern of an objective fine concavo-convex pattern and comprises plurality of fine convex parts and/or concave parts.

As the etching method, dry etching is preferred and specifically, reactive ion etching with SF₆ is preferred.

### EXAMPLES

The present invention is described in more detail below with reference to Examples, but the present invention is not construed as being limited to these Examples.

Examples 1 and 2 are Inventive Examples, and Example 3 is Comparative Example.

### Example 1

### (Step (a))

TiO₂—SiO₂ glass fine particles obtained by mixing TiCl₄ and SiCl₄ as glass-forming raw materials each after gasification, and heating and hydrolyzing (flame-hydrolyzing) them in oxyhydrogen flame were deposited and grown on a substrate for deposition to form a porous TiO₂—SiO₂ glass body.

Since the obtained porous TiO₂—SiO₂ glass body was difficult to handle without any treatment, the glass body was held in the air at 1,200° C. for 4 hours in the state of being still deposited on the substrate for deposition, and then removed from the substrate for deposition.

### (Step (b))

The obtained porous TiO₂—SiO₂ glass body was held at 1,450° C. for 4 hours under reduced pressure to obtain a TiO₂—SiO₂ dense body.

### (Step (c))

The obtained TiO₂—SiO₂ dense body was placed in a carbon mold, and held at 1,680° C. for 4 hours to obtain a transparent TiO₂—SiO₂ glass body.

### (Step (d))

The obtained transparent TiO₂—SiO₂ glass body was again placed in a carbon mold and held at 1,700° C. for 4 hours to obtain a molded TiO₂—SiO₂ glass body.

### (Step (e))

The obtained molded TiO₂—SiO₂ glass body was cooled to 1,000° C. at 10° C./hr in the furnace as it was and thereafter, kept at 1,000° C. for 3 hours. After cooled to 950° C. at 10° C./hr, the glass body was kept at 950° C. for 72 hours. After cooled to 900° C. at 5° C./hr, the glass body was kept at 900° C. for 72 hours and then cooled to 700° C. at 100° C./hr. Thereafter, the glass body was allowed to stand to be cooled to room temperature to obtain a TiO₂—SiO₂ glass body.

### (Evaluation)

With respect to the obtained TiO₂—SiO₂ glass body, TiO₂ concentration, Ti³⁺ concentration, ΔTi³⁺/Ti³⁺, OH concentration, halogen concentration, internal transmittance, stress, and coefficient of thermal expansion were determined by the methods described above. The results are shown in Table 1 and Table 2. Incidentally, the data for the TiO₂—SiO₂ glass body obtained in step (e) are not changed by cutting, shaving, polishing and the like in step (f) to be mentioned later.

### (Step (f))

The obtained TiO₂—SiO₂ glass body is cut into a plate shape of length of about 153.0 mm×width of about 153.0 mm×thickness of about 6.75 mm by using an inner-diameter saw slicer to prepare an unpolished TiO₂—SiO₂ glass plate.

The TiO₂—SiO₂ glass plate was chamfered so that longitudinal and transversal outer sizes were each about 152 mm and chamfered width was from 0.2 to 0.4 mm by using a commercially available NC chamfering machine with a diamond abrasive of #120. Using a 20B double-side lapper (manufactured by SPEEDFAM Co., Ltd.), the main surface of the TiO₂—SiO₂ glass plate was polished with SiC of #400 as an abrasive until the thickness became about 6.50 mm.

The side surface and the chamfered surface of the TiO₂—SiO₂ glass plate were polished by relatively moving a polishing brush having bristles for brushes protruded from a disk-like plate against the TiO₂—SiO₂ glass plate with feeding a polishing slurry containing a polishing abrasive (cerium oxide). Specifically, using a polishing apparatus described in Japanese Patent No. 2585727, the side surface and the chamfered surface were polished so that the bristles for brushes came into contact with the side surface and the chamfered surface of the TiO₂—SiO₂ glass plate uniformly over a whole surface to apply pressure.

As a first polishing, the main surface was polished about 50 μm by using a 20B double-side polisher with a slurry containing cerium oxide, as a main component, having a mean particle diameter of 1.5 um, which was an abrasive.

As a second polishing, the main surface was polished about 10 μm by using a 20B double-side polisher with a slurry containing cerium oxide, as a main component, having a mean particle diameter of 1.0 um, which was an abrasive.

As a third polishing, final polishing was performed by using a different polishing machine. In the final polishing, colloidal silica (COMPOL 20 manufactured by Fujimi Incorporated) was used as a polishing abrasive.

The TiO₂—SiO₂ glass plate after polishing was washed by using a multi-step automatic washing machine in which a hot solution of sulfuric acid and a hydrogen peroxide aqueous solution was used in the first tank and a neutral surfactant solution was used in the third tank.

### (Evaluation)

With respect to the obtained TiO₂—SiO₂ glass substrate, fictive temperature distribution, arithmetic average roughness and root mean square of concaves and convexes of the side surface, and arithmetic average roughness of the chamfered surface were determined by the aforementioned methods. The results are shown in Table 3.

Moreover, the obtained TiO₂—SiO₂ glass substrate is placed in a polymethyl methacrylate-made housing case in a clean room and a vibration test for a housing case is performed in accordance with MIL-STD-810F of Military Specifications and Military Standards.

After the vibration test, the housing case is opened in a clean room. With respect to the TiO₂—SiO₂ glass substrate taken out, the number of defects owing to attached foreign matters on the main surface is measured by using a defect inspection apparatus (M1320 manufactured by Lasertec Corporation) and evaluated according to the following criteria. The results are shown in Table 3.

A: Almost no difference is observed in the number of defects before and after the vibration test.

B: The number of defects was obviously increased after the vibration test as compared with the number before the vibration test.

### Example 2

A TiO₂—SiO₂ glass substrate is obtained in the same manner as in Example 1, except that polishing of the side surface and the chamfered surface of the TiO₂—SiO₂ glass plate in Step (f) was performed by using a polishing brush in which a brush was protruded from a roll-like support toward an outer peripheral direction, rotating the TiO₂—SiO₂ glass plate with an axis perpendicular to the main surface of the TiO₂—SiO₂ glass plate being as a rotation axis, and bringing the glass plate into contact with the rotated roll-like brush. The results are shown in Tables 1 to 3.

### Example 3

A TiO₂—SiO₂ glass substrate is obtained in the same manner as in Example 1, except that the step (e) was not conducted in the preparation method of a glass body. The results are shown in Tables 1 to 3.

TABLE 1

| | TiO₂ concentration | Ti³⁺ concentration | | OH concentration | Halogen concentration | T₄₀₀₋₇₀₀ | T₃₀₀₋₇₀₀ | T₃₀₀₋₃₀₀₀ |
|---|---|---|---|---|---|---|---|---|
| Example | [mass %] | [wt ppm] | ΔTi³⁺/Ti³⁺ | [wt ppm] | [wt ppm] | [%] | [%] | [%] |
| 1 | 6.7 | 6.8 | 0.08 | 40 | <50 | 93.8 | 88.7 | 88.7 |
| 2 | 6.7 | 7.1 | 0.09 | 40 | <50 | 93.6 | 88.6 | 88.6 |
| 3 | 6.2 | 6.8 | 0.09 | 40 | <50 | 94.0 | 88.6 | 88.6 |

TABLE 2

| | | | Coefficient of | Coefficient of |
|---|---|---|---|---|
| | | | thermal expansion | thermal expansion |
| | dev[σ] | Δσ | at 15 to 35° C. | at 22° C. |
| | [MPa] | [MPa] | C₁₅₋₃₅ [ppb/° C.] | C₂₂ [ppb/° C.] |
| Example 1 | 0.03 | 0.13 | −14 to 24 | less than 0 ± 3 |
| Example 2 | 0.03 | 0.13 | | |
| Example 3 | 0.07 | 0.24 | −33 to 61 | less than 0 ± 5 |

TABLE 3

| | | Fictive temperature | | MSFR_rms | Ra | |
|---|---|---|---|---|---|---|
| | Fictive temperature | distribution | Ra of side surface | of side surface | of chamfered surface | |
| | [° C.] | [° C.] | [nm] | [nm] | [nm] | Defect |
| Example 1 | 960 | <10 | 0.37 | 4.1 nm | 0.39 | A |
| Example 2 | 960 | <10 | 0.47 | 5.3 nm | 0.42 | |
| Example 3 | 1060 | 15 | 0.82 | 11 nm | 0.73 | B |

While the present invention has been described in detail and with reference to specific embodiments thereof, it will be apparent to one skilled in the art that various changes and modifications can be made therein without departing from the spirit and scope thereof.

The present application is based on Japanese Patent Application No. 2010-157811 filed on Jul. 12, 2010, and the contents are incorporated herein by reference.

### INDUSTRIAL APPLICABILITY

The TiO₂-containing quartz glass substrate for an imprint mold of the present invention is useful as a material for an imprint mold to be used for the purpose of forming a fine concave-convex pattern with a size of 1 nm to 10 μm in a semiconductor device, an optical waveguide, a micro-optical element (such as diffraction grating), a biochip, a microreactor, or the like.

### DESCRIPTION OF REFERENCE NUMERALS AND SIGNS

10 TiO₂-containing quartz glass substrate for imprint mold
12 Main surface
14 Side surface
16 Chamfered surface

1. A TiO₂-containing quartz glass substrate for an imprint mold having a main surface and a side surface, wherein
the side surface has an arithmetic average roughness (Ra) of 1 nm or less, and
the side surface has a root mean square (MSFR_rms) of concaves and convexes in the wavelength region of from 10 μm to 1 mm being 10 nm or less.

2. The TiO₂-containing quartz glass substrate for an imprint mold according to claim 1, having a chamfered surface intervening between the main surface and the side surface, wherein
the chamfered surface has an arithmetic average roughness (Ra) of 1 nm or less.

3. The TiO₂-containing quartz glass substrate for an imprint mold according to claim 1, having a TiO₂ concentration of from 3 to 12 mass %.

4. The TiO₂-containing quartz glass substrate for an imprint mold according to claim 1, having a standard deviation (dev[σ]) of stress caused by striae being 0.05 MPa or less.

5. The TiO₂-containing quartz glass substrate for an imprint mold according to claim 1, having a difference (Δσ) between the maximum value and the minimum value of stress caused by striae of 0.23 MPa or less.

6. A method for producing a TiO₂-containing quartz glass substrate for an imprint mold having a main surface and a side surface, comprising:
polishing a side surface of a TiO₂-containing quartz glass substrate having a standard deviation (dev[σ]) of stress caused by striae of 0.05 MPa or less,
thereby controlling arithmetic average roughness (Ra) of the side surface to 1 nm or less and
controlling root mean square (MSFR_rms) of concaves and convexes of the side surface in the wavelength region of from 10 μm to 1 mm to 10 nm or less.

7. A method for producing a TiO₂-containing quartz glass substrate for an imprint mold having a main surface and a side surface, comprising:
polishing a side surface of a TiO₂-containing quartz glass substrate having a difference (Δσ) between the maximum value and the minimum value of stress caused by striae of 0.23 MPa or less,
thereby controlling arithmetic average roughness (Ra) of the side surface to 1 nm or less and
controlling root mean square (MSFR_rms) of concaves and convexes of the side surface in the wavelength region of from 10 μm to 1 mm to 10 nm or less.

8. The method for producing a TiO₂-containing quartz glass substrate for an imprint mold according to claim 6, wherein the side surface of the TiO₂-containing quartz glass substrate is polished by relatively moving a polishing brush having bristles for brushes protruded therefrom against the TiO₂-containing quartz glass substrate, with feeding a polishing slurry containing a polishing abrasive.

9. The method for producing a TiO₂-containing quartz glass substrate for an imprint mold according to claim 6,
wherein the TiO₂-containing quartz glass substrate has a chamfered surface intervening between the main surface and the side surface and
the method comprises polishing the chamfered surface together with the side surface of the TiO₂-containing quartz glass substrate,
thereby controlling arithmetic average roughness (Ra) of the chamfered surface to 1 nm or less.
